(19) United States
(12) Patent Application Publication
(10) Pub. No.: US 2012/0006376 A1
(43) Pub. Date: Jan. 12, 2012

(54) ELECTRICAL CONTACTS FOR SKUTTERUDITE THERMOELECTRIC MATERIALS

(75) Inventors: JEAN-PIERRE FLEURIAL, Altadena, CA (US); Thierry Caillat, Pasadena, CA (US); Su Chih Chi, Baltimore, MD (US)

(73) Assignee: California Institute of Technology, Pasadena, CA (US)

(21) Appl. No.: 13/161,156

(22) Filed: Jun. 15, 2011

Related U.S. Application Data
(60) Provisional application No. 61/355,096, filed on Jun. 15, 2010.

(51) Int. Cl. H01L 35/32; H01L 35/34; H01L 35/18

(52) U.S. Cl. 136/240; 136/201

(57) ABSTRACT

A thermally stable diffusion barrier for bonding skutterudite-based materials with metal contacts is disclosed. The diffusion barrier may be employed to inhibit solid-state diffusion between the metal contacts, e.g. titanium (Ti), nickel (Ni), copper (Cu), palladium (Pd) or other suitable metal electrical contacts, and a skutterudite thermoelectric material including a diffusible element, such as antimony (Sb), phosphorous (P) or arsenic (As), e.g. n-type CoSb₃ or p-type CeFe₄₋ₓCoₓSb₁₂ where the diffusible element is Sb, to slow degradation of the mechanical and electrical characteristics of the device. The diffusion barrier may be employed to bond metal contacts to thermoelectric materials for various power generation applications operating at high temperatures (e.g. 673 K or above). Some exemplary diffusion barrier materials have been identified such as zirconium (Zr), hafnium (Hf), and yttrium (Y).

### CROSS-REFERENCE TO RELATED APPLICATIONS

This application claims the benefit under 35 U.S.C. §119(e) of the following U.S. provisional patent application, which is incorporated by reference herein:

U.S. Provisional Patent Application No. 61/355,096, filed Jun. 15, 2010, and entitled “THERMALLY STABLE LOW RESISTANCE ELECTRICAL CONTACTS FOR SKUTTERUDITE THERMOELECTRIC MATERIALS”, by Fleurial et al. (Attorney Docket CIT-5609-P).

### STATEMENT OF GOVERNMENT RIGHTS

The invention described herein was made in the performance of work under a NASA contract, and is subject to the provisions of Public Law 96-517 (35 USC 202) in which the Contractor has elected to retain title.

### BACKGROUND OF THE INVENTION

1. Field of the Invention

This invention relates to thermoelectric devices. Particularly, this invention relates to electrical contacts for skutterudite thermoelectric materials in thermoelectric devices.

2. Description of the Related Art

Thermoelectric materials exhibit the property of producing an electric voltage from an applied temperature differential across the material, the so-called thermoelectric effect of Peltier-Seebeck effect. Accordingly, such materials may be used in thermoelectric devices to generate electrical power from a temperature differential. Such thermoelectric generators have been used to convert heat directly to electrical power for applications including isolated facilities or space applications. Depending upon the application, the applied heat may be naturally available or generated, e.g. by burning fuel or from a decaying radioisotope.

Previously, thermoelectric power generation for deep space applications have employed SiGe thermoelectric materials generating electric power using a decaying radioisotope, e.g. plutonium 238, as a heat source, in a radioisotope thermoelectric generator (RTG). The fuel source and solid state nature of the devices afford exceptional service life and reliability, paramount considerations in space applications which offset the relatively low efficiency of such devices. Many working RTG devices for space applications have been developed and successfully employed. See e.g. Winter et al., “The Design of a Nuclear Power Supply with a 50 Year Life Expectancy: The JPL Voyager's SiGe MHW RTG,” IEEE AES Systems Magazine, April 2000, pp. 5-12; and U.S. Pat. No. 3,822,152, issued Jul. 2, 1974 to Kot, which are incorporated by reference herein.

Development of vehicle exhaust waste heat recovery systems based on thermoelectrics is also currently being very actively pursued by a number of research and industrial groups located in North America, Europe and Asia. In the United States since 2004, the Department of Energy (DOE) has supported a program entitled “Waste Heat Recovery and Utilization Research and Development for Passenger Vehicle and Light/Heavy Duty Truck Application.” The program identifies a goal of demonstrating a 10% fuel consumption improvement, without increasing emissions, by reducing the mechanical load due to the vehicle alternator.

100081 In addition, there has been increased interest in the potential of thermoelectric technology to recover waste heat from heat sources generated by large scale energy intensive industrial processes and machinery, or by the combustion engine exhaust of transportation vehicles. Certain issues may arise in the development of suitable components for thermoelectric devices regardless of the type of heat source employed which depend only upon the type of thermoelectric material and possibly the applicable operating temperature.

In previous years, extensive technology development has been made on a family of new high temperature thermoelectric materials, called skutterudites, and power generating devices based on these materials. Skutterudite material properties are described in Fleurial et al., “Skutterudites: An Update,” Proceedings of the XVI International Conference on Thermoelectrics, Dresden, Germany, August 26-29, 1997, which is incorporated by reference herein. Skutterudite materials, such as n-type CoSb₃ and p-type CeFe₄₋ₓCoₓSb₁₂, are currently some of the best candidates for the expected operating temperature range of vehicle exhaust waste heat power generator, due to their relatively low cost, low toxicity and suitable mechanical properties. However, one of the limitations of the skutterudite thermoelectric materials previously reported is thermal stability; some of the internal electrical contact interfaces to the thermoelectric materials may fail under high temperature operating conditions (e.g. up to 950 K for typical skutterudite thermoelectric materials).

Differences in the physical, mechanical and chemical properties of the materials that make up the thermoelectric device, particularly differences in the coefficients of thermal expansion (CTE), may result in undesirable stresses at material interfaces that can lead to mechanical failure of the device. These problems may be more significant in thermoelectric devices because thermoelectric materials have relatively large CTE values and are brittle, so cracks can propagate through them with minimal resistance. These factors limit the choice of available metals and ceramics for thermoelectric device fabrication. In addition, other potential degradation mechanisms, such as thermally-driven interdiffusion at metal/thermoelectric material interfaces over time can lead to catastrophic failures in thermoelectric device.

Previous work has demonstrated that high performance skutterudite power generating couples may be fabricated using single thick titanium (Ti) layers and dual cobalt/titanium (Co/Ti) layers as metal electrodes for n-type and p-type skutterudite thermoelectric elements (also referred to as “legs” of the thermoelectric power generator), respectively. The bonded metal/skutterudite interfaces can provide reduced mechanical stresses and very low electrical contact resistances. However, subsequent extended testing of the skutterudite-metal couplings at high hot side operating temperatures (850° K and higher) have demonstrated that there was extensive diffusion of antimony (Sb) into the Ti electrodes, eventually leading to significant degradation of the interface morphology and overall device performance.

In view of the foregoing, there is a need in the art for apparatuses and methods for improved thermoelectric material coupling, e.g. for electrical contacts in thermoelectric devices. There is particularly a need for such apparatuses and methods in skutterudite-based thermoelectric devices operating at high temperatures with high grade heat sources, e.g. around or above 850 K and higher. There is a need for such apparatuses and methods to extend the service life and performance of such thermoelectric devices. There is a particular need for such apparatuses and methods to operate for such thermoelectric devices in space applications, such as the radioisotope thermoelectric generators that support some of NASA's deep space exploration science missions. In addition, such technologies may also benefit waste heat recovery systems for heavy industry and automotive applications. These and other needs are met by embodiments of the present invention as detailed hereafter.

### SUMMARY OF THE INVENTION

A thermally stable diffusion barrier for bonding skutterudite-based materials with metal contacts is disclosed. The diffusion barrier may be employed to inhibit solid-state diffusion between the metal contacts, e.g. titanium (Ti), nickel (Ni), copper (Cu), palladium (Pd) or other suitable metal electrical contacts, and a skutterudite thermoelectric material including a diffusible element, such as antimony (Sb), phosphorous (P) or arsenic (As), e.g. n-type CoSb₃ or p-type CeFe₄₋ₓCoₓSb₁₂, where Sb is the diffusible element, to slow degradation of the mechanical and electrical characteristics of the device. The diffusion bather may be employed to bond metal contacts to thermoelectric materials for various power generation applications operating at high temperatures (e.g. at or above 673 K). Some exemplary diffusion barrier materials have been identified such as zirconium (Zr), hafnium (Hf), and yttrium (Y).

A typical embodiment of the invention comprises a thermoelectric device, including a skutterudite thermoelectric material comprising a diffusible element selected from the group of antimony antimony (Sb), phosphorous (P) and arsenic (As), the skutterudite thermoelectric material for generating electrical power from heat, a metal contact electrically coupled to the skutterudite thermoelectric material, and a diffusion bather bonded between the skutterudite thermoelectric material and the metal contact for inhibiting solid-state diffusion of the diffusible element to the metal contact. Typically, the skutterudite thermoelectric material may comprise n-type CoSb₃ or p-type CeFe₄₋ₓCoxSb₁₂, where Sb is the diffusible element. The diffusion barrier may comprise zirconium (Zr), hafnium (Hf), or yttrium (Y) and the metal contact may comprise titanium (Ti), nickel (Ni), copper (Cu), or palladium (Pd).

In some embodiments of the invention, the diffusion barrier comprises a foil bonded to the skutterudite thermoelectric material with heat and pressure, such as in a hot pressing process. The foil may be at least 16 μm thick. (Significantly larger thicknesses may also be suitable, e.g. 25 or 125 μm thick, provided the metal contact remains electrically coupled, i.e. conductive, to the skutterudite thermoelectric material and Sb diffusion remains suitably inhibited.) The skutterudite thermoelectric material may comprise a powder which is solidified by the heat and pressure as the foil is bonded to it. Similarly, the metal contact may be bonded to the foil with the heat and pressure, i.e. as the foil is being bonded to the skutterudite thermoelectric material.

Embodiments of the invention may employ the diffusion barrier operating at least at 673 K. The heat may be provided from a decaying radioisotope, industrial waste heat, automotive exhaust waste heat, or any other suitable heat source as will be appreciated by those skilled in the art.

A typical method embodiment of the invention of forming a diffusion barrier between a skutterudite thermoelectric material and metal, comprises providing a skutterudite thermoelectric material comprising a diffusible element selected from the group of antimony antimony (Sb), phosphorous (P) and arsenic (As), the skutterudite thermoelectric material for generating electrical power from heat, bonding a diffusion barrier to the skutterudite thermoelectric material, and bonding a metal contact to the diffusion barrier. The metal contact is electrically coupled to the skutterudite thermoelectric material and the diffusion barrier inhibits solid-state diffusion of the diffusible element to the metal contact. In some embodiments of the invention, the method may further comprise cleaning and etching of the metal contact and the diffusion barrier prior to bonding. The method embodiment of the invention may be further modified consistent with the apparatus embodiments described herein.

Another typical embodiment of the invention may comprise a thermoelectric device a skutterudite thermoelectric material means for generating electrical power from heat, the skutterudite thermoelectric material means comprising a diffusible element selected from the group of antimony antimony (Sb), phosphorous (P) and arsenic (As), a metal contact means for electrically coupling to the skutterudite thermoelectric material means, and a diffusion barrier means for inhibiting solid-state diffusion of the diffusible element to the metal contact means, the diffusion barrier means disposed between the skutterudite thermoelectric material and the metal contact means. This embodiment of the invention may be further modified consistent with the apparatus or method embodiments described herein.

### BRIEF DESCRIPTION OF THE DRAWINGS

Referring now to the drawings in which like reference numbers represent corresponding parts throughout:

FIG. 1 is a schematic diagram of an exemplary thermoelectric device employing a thermoelectric material with a diffusion barrier between the metal contacts and the thermoelectric material;

FIG. 2 is a plot of electrical contact resistance measurements of an exemplary n-type skutterudite material bonded to metal employing a Zr diffusion barrier;

FIGS. 3A-3C show a magnified cross section image of an exemplary n-type metallized skutterudite using a 25 μZr diffusion barrier at beginning of life, after two months anneal at 773 K, and after two weeks anneal at 873 K, respectively;

FIGS. 4A-4C show a magnified cross section image of an exemplary n-type metallized skutterudite using a 16 μm Zr diffusion barrier at beginning of life, after two months anneal at 773 K, and after two weeks anneal at 873 K, respectively;

FIG. 5 shows a magnified cross section image of an exemplary p-type metallized skutterudite; and

FIG. 6 is a flowchart of an exemplary method of forming a diffusion barrier between a skutterudite thermoelectric material and metal for a thermoelectric device.

### DETAILED DESCRIPTION OF THE PREFERRED EMBODIMENT

1. Overview

As previously mentioned, embodiments of the present invention is directed to the fabrication of advanced high temperature interfaces, e.g. for electrical contacts, in skutterudite thermoelectric devices, such as thermoelectric power generation devices. Such devices typically require the joining of several dissimilar materials. In order to achieve a device capable of operating at elevated temperatures across a large temperature differential, a number of diffusion bonding and/or brazing processes may be employed. A typical thermoelectric device may comprise a heat collector/exchanger, metal connector interfaces on both the hot and cold sides, n-type and p-type conductivity thermoelectric elements, and cold side hardware to couple to the cold side heat rejection element as will be understood by those skilled in the art.

Embodiments of the invention may be applied to thermoelectric devices including a skutterudite thermoelectric material comprising a diffusible element selected from the group of antimony antimony (Sb), phosphorous (P) and arsenic (As). A diffusion barrier is used to inhibit diffusion of the diffusible element to a metal contact. Some example embodiments of the present invention employ a diffusion barrier that enables the formation of refractory Sb based compounds more stable than the Sb-based Ti compound which has been shown to result from a Ti metal contact bonded directly to a Sb-rich skutterudite thermoelectric material. The novel diffusion barrier exhibits very low kinetics of Sb self-diffusion. Embodiments of the present invention improve skutterudite thermoelectric device technology by employing this diffusion barrier.

In one novel embodiment, a thermally stable diffusion bather is employed in bonding skutterudite-based materials with metal contacts, such as titanium (Ti), in a thermoelectric device. Such a diffusion barrier may be used to inhibit solid-state diffusion between the metal contacts and Sb-rich skutterudite thermoelectric components while not degrading the existing mechanical and electrical characteristics of the device.

2. Diffusion Barrier Between Skutterudite Materials and Metal Contacts

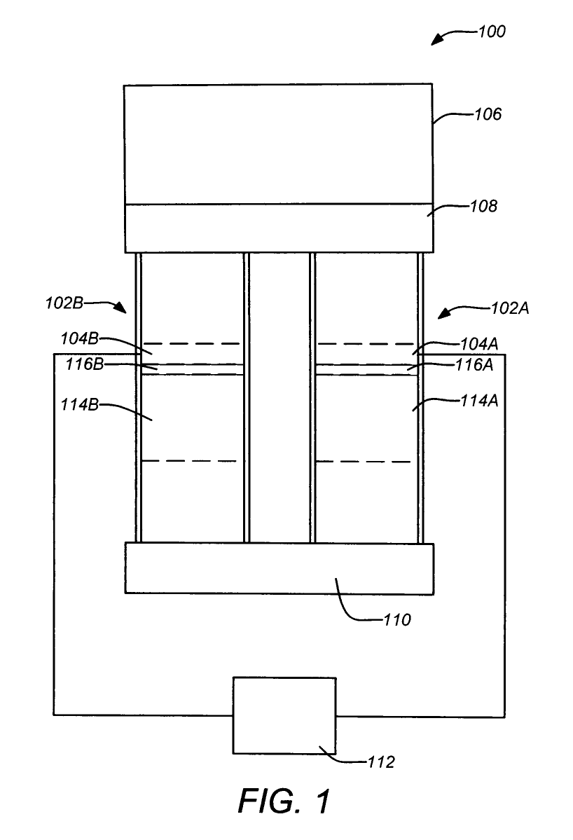

FIG. 1 is a schematic diagram of an exemplary thermoelectric device 100 employing two thermoelectric material elements 102A, 102B. The thermoelectric material elements 102A, 102B of the thermoelectric device 100 generate electrical power directly from the applied thermal gradient between the hot shoe 108 at one end and the cold shoe 110 at the other end. One of the thermoelectric material elements 102B acts as an n-type material providing excess electrons while the other thermoelectric material element 102A acts as an p-type material with deficient electrons.

At least one of the thermoelectric elements 102A, 102B comprises a skutterudite thermoelectric material 114A, 114B electrically coupled to a metal contact 104A, 104B having a diffusion barrier 116A, 116B therebetween. (Although metal contacts 104A, 104B and diffusion barriers 116A, 116B are only shown on one side of the skutterudite thermoelectric materials 114A, 114B, other diffusion barriers and metal contacts may be developed on any side of the thermoelectric materials 114A, 114B depending upon the application requirements.) Typically, a skutterudite thermoelectric material such as CeFe₄₋ₓCoₓSb₁₂ may be employed for the p-type thermoelectric material element 102A, while another thermoelectric material such as CoSb₃ may be employed for the n-type thermoelectric material element 102B. In this example the diffusible element is Sb, the metal contacts 104A, 104B comprise titanium (Ti) and the diffusion barriers 116A, 116B comprise zirconium (Zr).

It should be noted that those skilled in the art will understand that embodiments of the invention may also employ other combinations of materials in accordance with the principles describe herein. For example, other skutterudite thermoelectric materials having alternate diffusible elements, such as phosphorous (P) or arsenic (As), may also be employed in embodiments of the invention. Similarly, the metal contacts 104A, 104B may alternately comprise nickel (Ni), copper (Cu), palladium (Pd) or other suitable metal instead of Ti. Diffusion barriers 116A, 116B may alternately be developed from hafnium (Hf) or yttrium (Y). Optimum material combinations may be readily determined through testing according to the principles described hereafter.

The two thermoelectric material elements 102A, 102B are thermally coupled in parallel between the hot shoe 108 and cold shoe 110 but electrically isolated from one another. Heat is provided to the hot shoe 108 from a coupled heat source 106, e.g. a decaying radioisotope such as plutonium 238, industrial or automotive exhaust waste heat, or any other suitable heat source capable of generating suitable temperatures, e.g. at or above 673 K. In contrast, the cold shoe 110 at the opposing end typically includes a radiator for rejecting heat to enhance the temperature differential across the thermoelectric material elements 102A, 102B. Electrical power may be yielded from an electrical series connection across the two thermoelectric material elements 102A, 102B. Typically, the electrical power is coupled to a power system 112 which may include a regulator and/or battery subsystems as known in the art.

It should be noted that the thermoelectric device 100 depicted in FIG. 1 is not to scale and presents only a generalized thermoelectric power generation device. The thermoelectric device 100 is just one example configuration of an embodiment of the invention utilizing diffusion barrier for a skutterudite thermoelectric material. Those skilled in the art will appreciate that the general configurations of previously developed thermoelectric power generation devices may be employed, e.g. SiGe and other RTGs, but with a skutterudite thermoelectric element employing a diffusion barrier to a metal contact.

Those skilled in the art will also understand that each thermoelectric element 102A, 102B may comprise a combination of thermoelectric materials. A combination of layered different thermoelectric materials may be employed across the operational thermal gradient of the device to optimize overall performance based upon the particular application requirements. For example, a practical power generation device may employ multiple stages each tuned to a specific temperature range and coupled together to produce more power. A p-type Zintl (such as Yb₁₄MnSb₁₁) and n-type La₃₋ₓTe₄ thermoelectric materials may be used in combination with skutterudite thermoelectric materials in segmented stages capable of operating with a very high peak temperature (e.g. 1273 K). In these couples, the skutterudite thermoelectric material stages may be used between at more moderate temperatures of the gradient (e.g. between about 473 K and 873 K). Embodiments of the invention will benefit wherever it is desired to bond metal (e.g. to form electrical connections) to any portion of the overall thermoelectric elements 102A, 102B which may comprise a skutterudite thermoelectric material having a diffusible element as described. In general, skutterudite thermoelectric materials employing a diffusion barrier may be operated at temperatures as high as 973 K, with typical service temperatures ranging from approximately 773 K to 873 K.

In addition, the thermoelectric elements 102A, 102B may also include other materials, e.g. to facilitate electrical connection to the power system 112 and electrical isolation, e.g. graphite barriers may be employed in the element stack. The heating element 106 need not be directly adjacent to the hot shoe 108 but may only be thermally coupled to the hot shoe 108 instead. Furthermore, the skutterudite thermoelectric materials and diffusion barriers may also be employed in combination with other thermoelectric technologies. For example, some thermoelectric materials may also require sublimation suppression barriers, e.g. to inhibit Sb sublimation. See e.g. U.S. Pat. No. 7,461,512 by Sakamoto et al., entitled “System and Method for Suppressing Sublimation Using Opacified Aerogel,” issued Dec. 9, 2008, and U.S. Pat. No. 6,660,926 by Fleurial et al., entitled “Thermoelectric Device Based on Materials with Filled Skutterudite Structures,” issued Dec. 9, 2003, which are incorporated by reference herein.

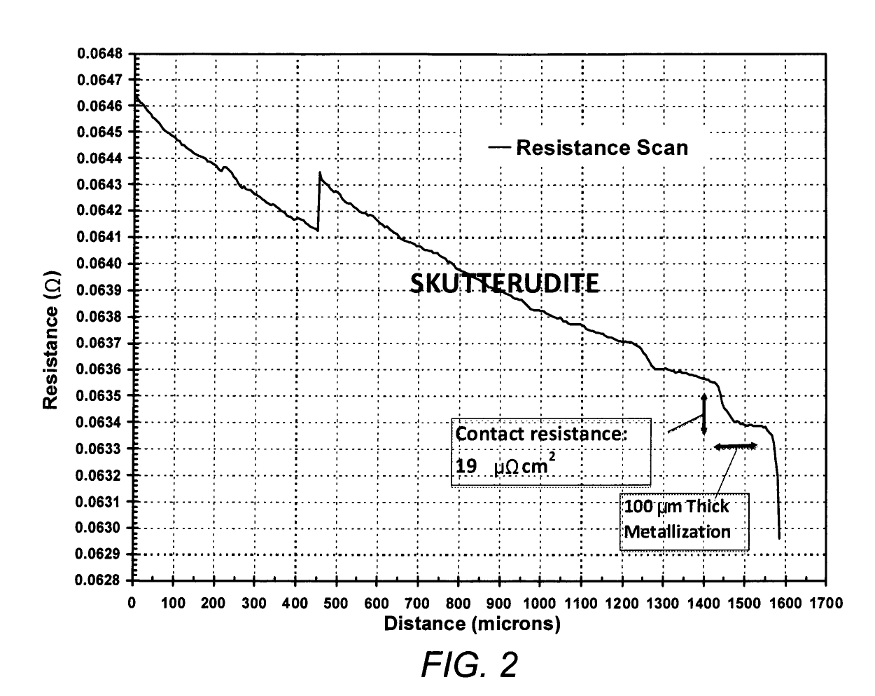

FIG. 2 is a plot of electrical contact resistance measurements of an exemplary n-type skutterudite material bonded to a metal contact employing an example Zr diffusion barrier. Electrical contact resistance measurements have shown that the contact resistance values are low enough to meet typical thermoelectric device performance requirements, usually less than 25 μΩ-cm². The plot of FIG. 2 quantifies the small jump in resistance at the skutterudite/metallization interface. This measurement was performed at room temperature where contact resistance values are highest. These example results show that the contact resistance values are low enough to meet typical thermoelectric device performance requirements.

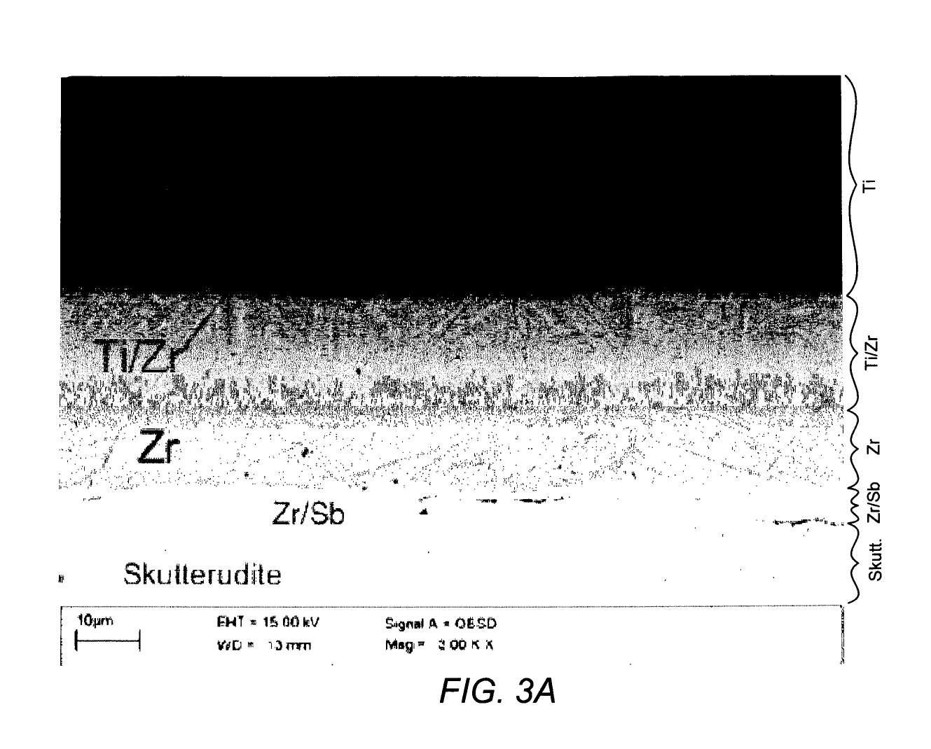

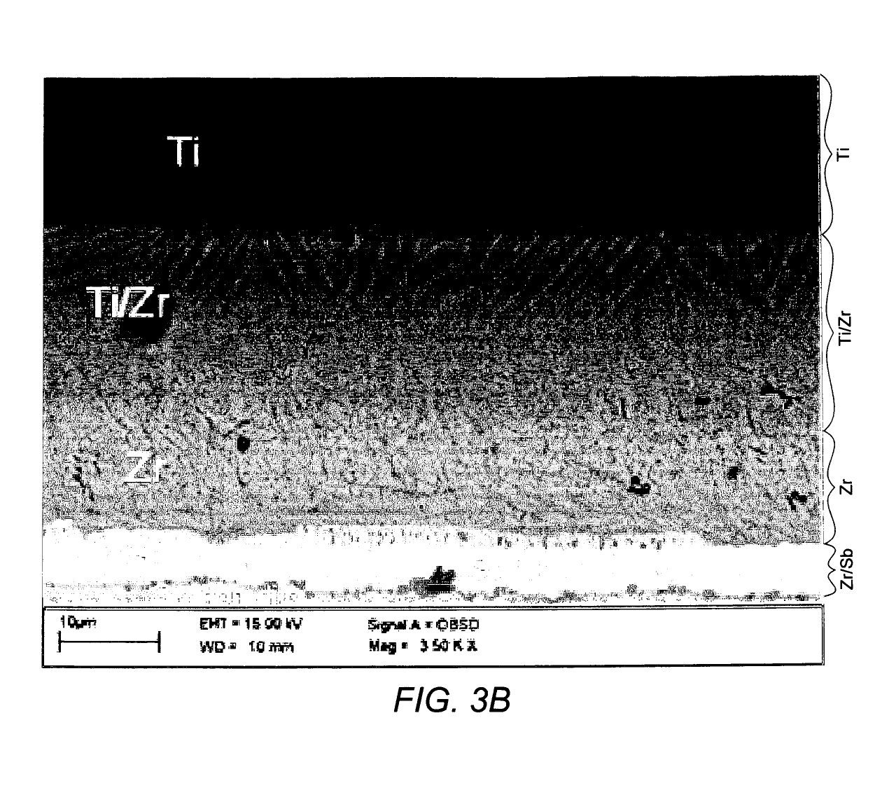

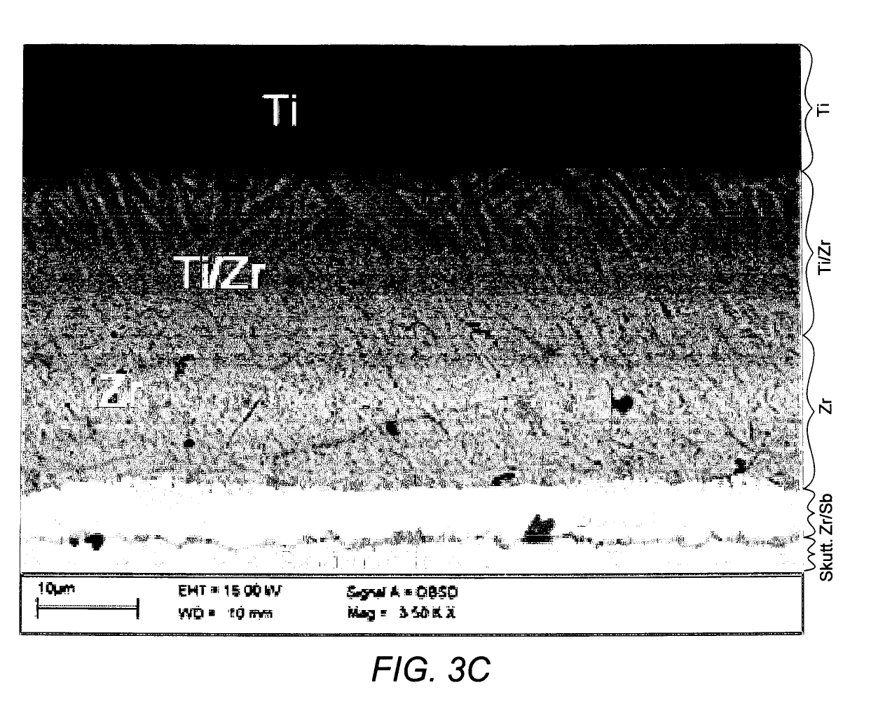

FIGS. 3A-3C show a magnified cross section image of an exemplary n-type metallized skutterudite using a 25 μm Zr diffusion barrier at beginning of life, after two months anneal at 773 K, and after two weeks anneal at 873 K, respectively. Metallized samples may be cross-sectioned to examine the chemical interactions between the n-type skutterudite thermoelectric material (e.g., CoSb₃), Ti metal contacts and Zr diffusion barrier using a scanning electron microscope (SEM) and electron dispersive spectroscopy (EDS).

FIG. 3A shows continuous bonding interfaces at each distinct material layer. It can be seen that part of the Zr diffusion barrier foil remained after the initial hot-pressing temperature process (a thickness of approximately 10 μm). On the top of pure Zr layer, Ti reacts with Zr to form a Ti/Zr solid solution. On the skutterudite-side, Sb was diffused into Zr and formed the refractory ZrSb₂ compound, which effectively acts as a barrier to prevent further diffusion of the Sb into the thick Ti electrode material. Without the diffusion barrier, direct bonding between skutterudite and the Ti resulted in the Ti metal contact acting as a “Sb sink” through the continuous formation of TiSb₂. This was previously identified as a failure mechanism for prior art devices.

In addition, metalized junctions using example 25 μm Zr foils and 125 μm Ti foils were tested by annealing for two months in ampoules under high vacuum at the temperatures of 773 K and 873 K, respectively, to evaluate the chemical diffusion and thermal and mechanical stability. As shown in FIGS. 3B and 3C, the metallization layer is thermally stable, exhibiting no de-bonding and no access of diffusion between Sb from the skutterudite material and the thick Ti metal contact after the anneal.

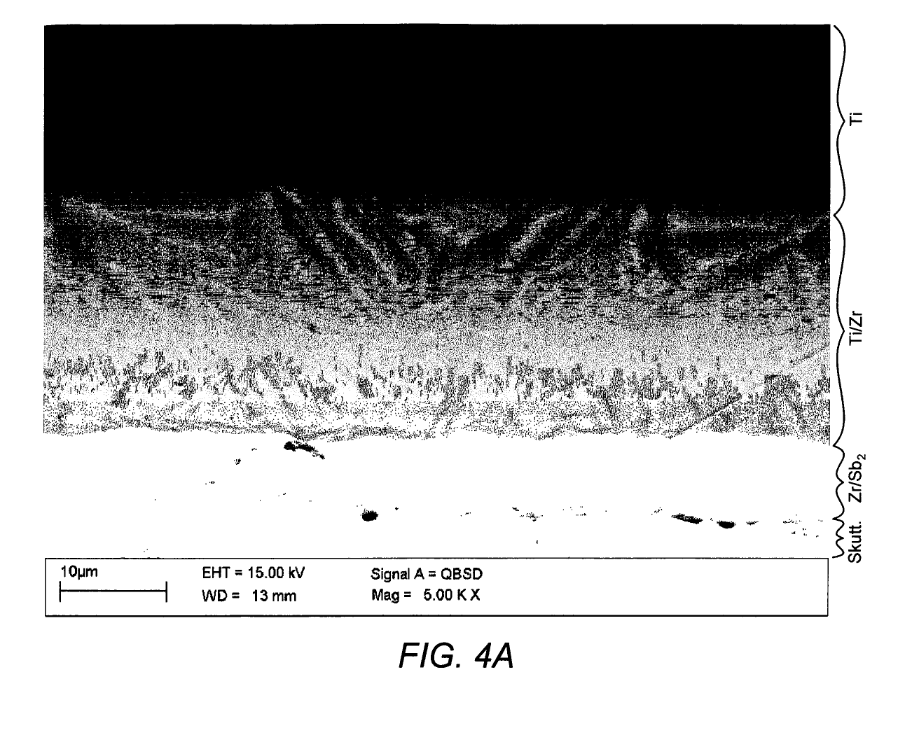

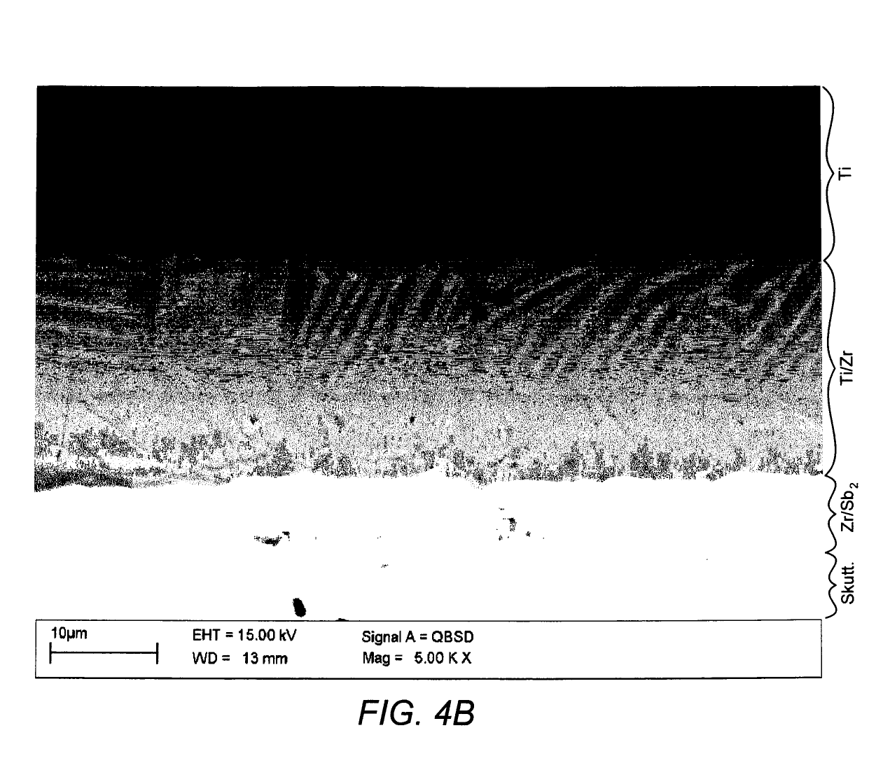

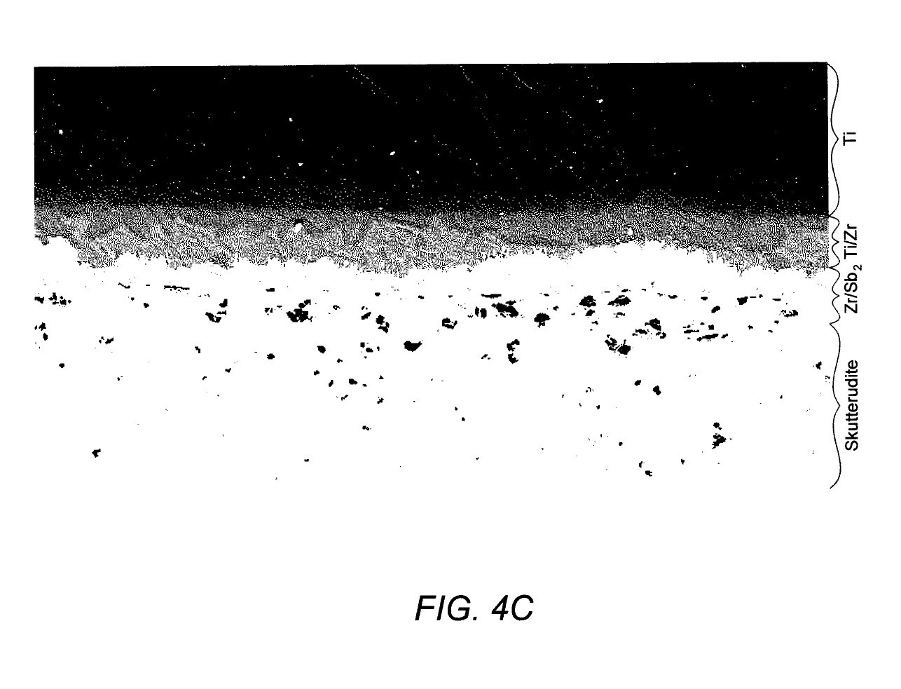

FIGS. 4A-4C show a magnified cross section image of an exemplary n-type metallized skutterudite using a 16 μm Zr diffusion barrier at beginning of life, after two weeks anneal at 773 K, and after two weeks anneal at 873 K, respectively. FIG. 4A shows the beginning of life metalized sample. In this example, metalized junctions using 16 μm Zr foils and 125 μm Ti foils were annealed for two months in sealed ampoules under high vacuum at the temperatures of 773 K and 83 K, respectively, to determine the chemical diffusion and thermal and mechanical stability. As shown in FIGS. 4B and 4C, the metallization layer is thermally stable, exhibiting no de-bonding and no access of diffusion between Sb from the skutterudite material and the thick Ti metal contacts after the anneal.

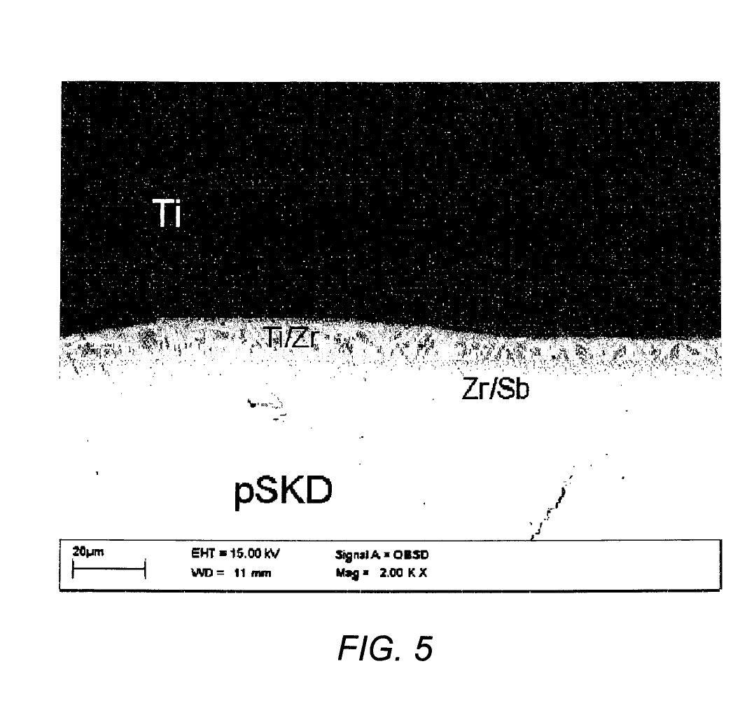

FIG. 5 shows a magnified cross section image of an exemplary p-type metallized skutterudite. In this example, backscattered electrons images show the Ti/Zr metallization applied to p-type filled skutterudite of CeFe₄₋ₓCoₓSb₁₂. Thus, it is shown that similar consistent results may also be shown for both double-filled n-type CoSb₃ samples and p-type CeFe₄₋ₓCoₓSb₁₂ filled samples.

4. Forming a Diffusion Barrier Skutterudite Thermoelectric Materials

Embodiments of the invention also encompass a method of forming a diffusion barrier between a skutterudite thermoelectric material and a metal contact. As discussed above, a diffusion barrier is important in order to inhibit diffusion from the skutterudite thermoelectric materials to improve thermoelectric performance and life operating at high temperatures.

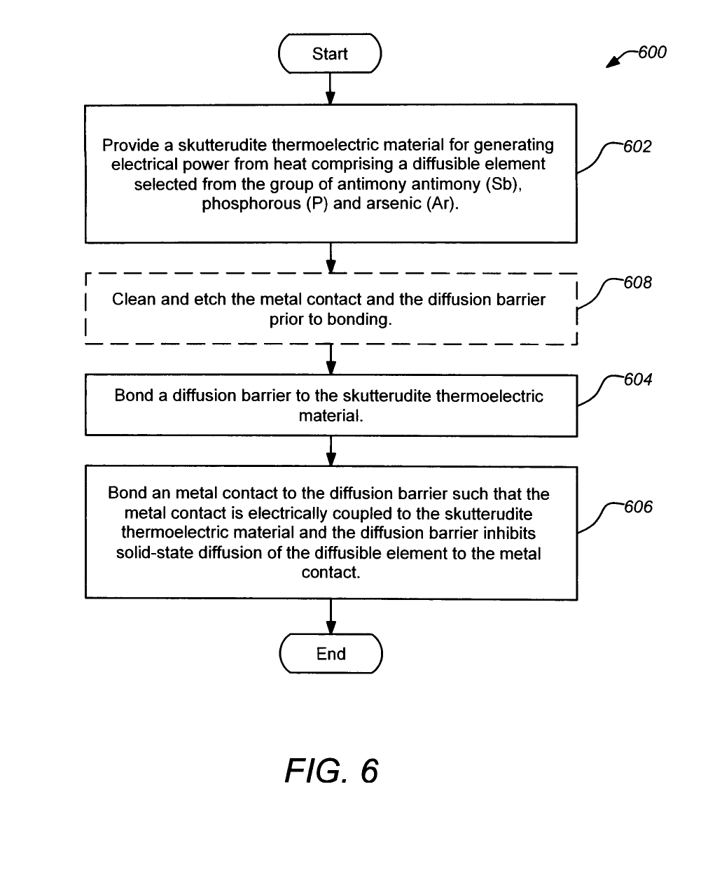

FIG. 6 is a flowchart of an exemplary method 600 of forming a diffusion barrier for a skutterudite thermoelectric material. The method 600 begins with an operation 602 of providing a skutterudite thermoelectric material for generating electrical power from heat comprising a diffusible element selected from the group of antimony antimony (Sb), phosphorous (P) and arsenic (As). In operation 604, a diffusion bather is bonded to the skutterudite thermoelectric material. Similarly, in operation 606, a metal contact is bonded to the diffusion bather. Bonding of the diffusion barrier is performed such that the metal contact is electrically coupled (i.e. conducts) to the skutterudite thermoelectric material and the diffusion bather inhibits solid-state diffusion of the diffusible element to the metal contact in operation. As described in the previous, the bonding may occur simultaneously at both interfaces, e.g. in a hot pressing process. Those skilled in the art will appreciate that bonding the diffusion bather to the metal contact and to the skutterudite thermoelectric material may be achieved through other known suitable processes as well.

The method 600 of forming a diffusion barrier for a skutterudite thermoelectric material may also be further modified by other optional operations. For example, the method 600 may further include the optional operation 608 of cleaning and etching of the metal contact and the diffusion barrier prior to bonding. Note that the optional operation 608 is indicated by dashed outlines in FIG. 6. The method 600 may also be further enhanced through optional operations consistent with the parameters described herein and any known techniques of semiconductor device manufacture and skutterudite thermoelectric material processing as will be understood by those skilled in the art.

The following provides a description of an example process that may be used to develop a desired metallization with a diffusion barrier. The example metallization process and the materials used for making Ti-terminated skutterudite thermoelectric pucks may be described as follows. Titanium (e.g. 125 micron thick foils) for a metal contact and zirconium (e.g. 16 or 25 micron thick foils) for a diffusion barrier are prepared with ultrasonic cleaning and etching. The etchant concentration may be 2HF:3HNO3:45H2O. The Ti foils, Zr foils and n-type skutterudite powder (e.g., CoSb₃) may be loaded in sequence into a graphite die. The powder may be cold pressed in between the loading of each material to achieve flat surfaces. A final hot pressing step may then be applied to simultaneously consolidate the powder and form the bonds between the diffusion barrier and the skutterudite thermoelectric material and metal contact. The hot pressing may be typically conducted at 1023 K and at a pressure of 18,000 psi for example.

While the example process described herein used metal foils and hot-pressing, those skilled in the art will appreciate that substantially similar results may be achieved with other known types of metallization techniques, e.g to develop Zr/Ti or other metallizations consistent with embodiments of the invention as described herein. Some example alternate processes include co-pressing (using spark plasma sintering or other powder metallurgy compaction techniques), sputtering of metals onto the pre-compacted skutterudites, ink printing and other known chemical deposition processes.

This concludes the description including the preferred embodiments of the present invention. The foregoing description including the preferred embodiment of the invention has been presented for the purposes of illustration and description. It is not intended to be exhaustive or to limit the invention to the precise forms disclosed. Many modifications and variations are possible within the scope of the foregoing teachings. Additional variations of the present invention may be devised without departing from the inventive concept as set forth in the following claims.

What is claimed is:

1. A thermoelectric device, comprising:
a skutterudite thermoelectric material comprising a diffusible element selected from the group of antimony (Sb), phosphorous (P) and arsenic (As), the skutterudite thermoelectric material for generating electrical power from heat;
a metal contact electrically coupled to the skutterudite thermoelectric material; and
a diffusion barrier bonded between the skutterudite thermoelectric material and the metal contact for inhibiting solid-state diffusion of the diffusible element to the metal contact.

2. The thermoelectric device of claim 1, wherein the skutterudite thermoelectric material comprises n-type CoSb₃ or p-type CeFe₄₋ₓCoₓSb₁₂ and the diffusible element comprise Sb.

3. The thermoelectric device of claim 1, wherein the diffusion barrier comprises zirconium (Zr), hafnium (Hf), or yttrium (Y).

4. The thermoelectric device of claim 1, wherein the diffusion barrier comprises a foil bonded to the skutterudite thermoelectric material with heat and pressure.

5. The thermoelectric device of claim 4, wherein the foil is at least 16 μm thick.

6. The thermoelectric device of claim 4, wherein the skutterudite thermoelectric material comprises a powder solidified by the heat and pressure as the foil is bonded.

7. The thermoelectric device of claim 4, wherein the metal contact is bonded to the foil with the heat and pressure.

8. The thermoelectric device of claim 1, wherein the metal contact comprises titanium (Ti), nickel (Ni), copper (Cu), palladium (Pd).

9. A method of forming a diffusion barrier for a skutterudite thermoelectric material, comprising the steps of:
providing a skutterudite thermoelectric material comprising a diffusible element selected from the group of antimony (Sb), phosphorous (P) and arsenic (As), the skutterudite thermoelectric material for generating electrical power from heat;
bonding a diffusion barrier to the skutterudite thermoelectric material; and
bonding a metal contact to the diffusion barrier;
wherein the metal contact is electrically coupled to the skutterudite thermoelectric material and the diffusion barrier inhibits solid-state diffusion of the diffusible element to the metal contact.

10. The method of claim 9, wherein the skutterudite thermoelectric material comprises n-type CoSb₃ or p-type CeFe₄₋ₓCoₓSb₁₂ and the diffusible element comprise Sb.

11. The method of claim 9, wherein the diffusion barrier comprises zirconium (Zr), hafnium (Hf), or yttrium (Y).

12. The method of claim 9, wherein the diffusion barrier comprises a foil bonded to the skutterudite thermoelectric material with heat and pressure.

13. The method of claim 12, wherein the foil is at least 16 μm thick.

14. The method of claim 12, wherein the skutterudite thermoelectric material is provided as a powder solidified by the heat and pressure as the foil is bonded.

15. The method of claim 12, wherein the metal contact is bonded to the foil with the heat and pressure.

16. The method of claim 12, further comprising cleaning and etching of the metal contact and the diffusion barrier prior to bonding.

17. The method of claim 9, wherein the metal contact comprises titanium (Ti), nickel (Ni), copper (Cu), or palladium (Pd).

18. A thermoelectric device, comprising:
a skutterudite thermoelectric material means for generating electrical power from heat, the skutterudite thermoelectric material means comprising a diffusible element selected from the group of antimony (Sb), phosphorous (P) and arsenic (As);
a metal contact means for electrically coupling to the skutterudite thermoelectric material means; and
a diffusion barrier means for inhibiting solid-state diffusion of the diffusible element to the metal contact means, the diffusion barrier means disposed between the skutterudite thermoelectric material and the metal contact means.

19. The thermoelectric device of claim 18, wherein the diffusion barrier means comprises zirconium (Zr), hafnium (Hf), or yttrium (Y).

20. The thermoelectric device of claim 18, wherein the metal contact means comprises titanium (Ti), nickel (Ni), copper (Cu), or palladium (Pd).
